(19) United States
(12) Patent Application Publication
(10) Pub. No.: US 2004/0222508 A1
(43) Pub. Date: Nov. 11, 2004

(54) Semiconductor device, electronic device, electronic apparatus, method of manufacturing semiconductor device, and method of manufacturing electronic device

(76) Inventor: Akiyoshi Aoyagi, Atsugi-shi (JP)

Correspondence Address: HARNESS, DICKEY & PIERCE, P.L.C., P.O. BOX 828, BLOOMFIELD HILLS, MI, 48303, US

(21) Appl. No.: 10/801,933

(22) Filed: Mar. 16, 2004

(30) Foreign Application Priority Data
Mar. 18, 2003 (JP) 2003-074220

(51) Int. Cl. H01L 21/48; H01L 29/94

(52) U.S. Cl. 257/686; 438/109; 257/700

(57) ABSTRACT

A method and device are provided to realize a structure in which different kinds of chips are three-dimensionally mounted while suppressing the warpage of a carrier substrate. A semiconductor package PK12 in which stacked semiconductor chips 33a and 33b are wire-bonded to the carrier substrate 31 is stacked on a semiconductor package PK11 in which semiconductor chips 23a and 23b are mounted on both faces of the carrier substrate 21 by ACF bonding.

### RELATED APPLICATIONS

This application claims priority to Japanese Patent Application No. 2003-074220 filed Mar. 18, 2003 which is hereby expressly incorporated by reference herein in its entirety.

### BACKGROUND

1. Technical Field of the Invention

The present invention relates to a semiconductor device, an electronic device, an electronic apparatus, a method of manufacturing a semiconductor device, and a method of manufacturing an electronic device which are suitable for application to, in particular, a stacked structure of semiconductor packages.

2. Description of the Related Art

In a conventional semiconductor device, in order to. save space when semiconductor chips are mounted, for example, as disclosed in Japanese Unexamined Patent Application Publication No. 10-284683, a method of three-dimensionally mounting semiconductor chips on a carrier substrate is used.

However, according to a method of three-dimensionally mounting semiconductor chips via a carrier substrate, the carrier substrate is significantly warped because the linear expansion coefficients of the carrier substrate on both faces of the carrier substrate are different from each other.

Accordingly, an object of the present invention is to provide a semiconductor device, an electronic device, an electronic apparatus, a method of manufacturing a semiconductor device, and a method of manufacturing an electronic device, which are capable of realizing a structure in which different kinds of chips can be three-dimensionally mounted while suppressing the warpage of carrier substrates.

### SUMMARY

In order to achieve the above object, according to one aspect of the present invention, there is provided a semiconductor device, comprising: a first carrier substrate; a first semiconductor chip mounted face down on the first carrier substrate; a second semiconductor chip mounted face down on the reverse face of the first carrier substrate; a second carrier substrate; a third semiconductor chip mounted on the second carrier substrate; and protruding. electrodes for connecting the second carrier substrate to the first carrier substrate so that the second carrier substrate is held above the first semiconductor chip.

According to the above structure, it is possible to provide semiconductor chips made of the same material on both faces of the first carrier substrate and thereby reduce a difference in the linear expansion coefficients on both faces of the first carrier substrate. As a result, it is possible to stack the second carrier substrate on the first carrier substrate while suppressing warpage of the first carrier substrate and thereby realize a structure in which different kinds of chips are three-dimensionally mounted while ensuring good connection reliability between the first carrier substrate and the second carrier substrate.

Further, in a semiconductor device according to one aspect of the present invention, the second carrier substrate is fixed to the first carrier substrate so as to be mounted on the first semiconductor chip.

According to the above structure, it is possible to overlap the first semiconductor chip and the third semiconductor chip with each other. As a result, it is possible to reduce the mounting area when a plurality of semiconductor chips is mounted and thereby save space when the semiconductor chips are mounted.

In a semiconductor device according to one aspect of the present invention, the semiconductor device further comprises a sealant for sealing the third semiconductor chip.

According to the above structure, it is possible to prevent the third semiconductor chips from being eroded and broken and thereby improve the reliability of the third semiconductor chips.

Further, in a semiconductor device according to one aspect of the present invention, the sealant is a molded resin.

According to the above structure, it is possible to stack different kinds of packages including the second carrier substrate on the first carrier substrate and thereby realize a structure in which the semiconductor chips are three-dimensionally mounted even when the kinds of the semiconductor chips vary.

Further, in a semiconductor device according to one aspect of the present invention, the position of a sidewall of the sealant coincides with that of a sidewall of the second carrier substrate.

According to the above structure, it is possible to reinforce one entire surface of the second carrier substrate with a sealant for sealing the third semiconductor chip while suppressing an increase in the height when the second carrier substrate is stacked on the first carrier substrate and to seal the third semiconductor chip without dividing the sealant into cells. As a result, it is possible to increase the mounting area of the third semiconductor chip mounted on the second carrier substrate.

Further, in a semiconductor device according to one aspect of the present invention, the first semiconductor chip and the second semiconductor chip are connected to the first carrier substrate by pressure welding.

According to the above structure, it is possible to lower the temperature when the first semiconductor chip and the second semiconductor chip are connected to the first carrier substrate and thereby reduce warpage of the first carrier substrate when the first carrier substrate is actually used.

Further, in a semiconductor device according to one aspect of the present invention, at the same temperature, the elastic modulus of a semiconductor device comprising the first carrier substrate is different from that of a semiconductor device comprising the second carrier substrate.

According to the above structure, it is possible to suppress warpage of one carrier substrate by the other carrier substrate and thereby improve the connection reliability between the first carrier substrate and the second carrier substrate.

Further, in a semiconductor device according to one aspect of the present invention, the first carrier substrate on which the first semiconductor chip and the second semiconductor chip are mounted is a flip-chip-mounted ball grid array, and the second carrier substrate on which the third semiconductor chip is mounted is a mold-sealed ball grid array or a chip size package.

According to the above structure, it is possible to stack different kinds of packages while suppressing an increase in the height of a structure in which the semiconductor chips are three-dimensionally mounted and thereby save space when the semiconductor chips are mounted even when the kinds of the semiconductor chips vary.

Further, in a semiconductor device according to one aspect of the present invention, the third semiconductor chip comprises a structure in which a plurality of chips is stacked.

According to the above structure, it is possible to stack a plurality of third semiconductor chips of different kinds and sizes on the first semiconductor chip and thereby save space when the semiconductor chips are mounted, and it is possible to let the semiconductor chips have various functions.

Further, in a semiconductor device according to one aspect of the present invention, the third semiconductor chip comprises a structure in which a plurality of chips is mounted in parallel on the second carrier substrate.

According to the above structure, it is possible to arrange the plurality of third semiconductor chips on the first semiconductor chips while suppressing an increase in the height when the third semiconductor chips are stacked. As a result, it is possible to suppress the deterioration of the connection reliability when the semiconductor chips are three-dimensionally mounted and save space when the semiconductor chips are mounted.

Further, according to one aspect of the present invention, there is provides a semiconductor device, comprising: a first carrier substrate; a first semiconductor chip mounted face down on at least one face of the first carrier substrate; a second carrier substrate; a second semiconductor chip mounted on the second carrier substrate; a third semiconductor chip mounted on the reverse face of the second carrier substrate; and protruding electrodes connecting the second carrier substrate to the first carrier substrate.

According to the above structure, it is possible to provide semiconductor chips made of the same material on both sides of the second carrier substrate and thereby reduce a difference in the linear expansion coefficients on both sides of the second carrier substrate. As a result, it is possible to stack the second carrier substrate on the first carrier substrate while suppressing warpage of the second carrier substrate and thereby realize a structure in which different kinds of chips are three-dimensionally mounted while ensuring good connection reliability between the first carrier substrate and the second carrier substrate.

Further, according to one aspect of the present invention, there is provided a semiconductor device, comprising: a carrier substrate; a first semiconductor chip mounted face down on the carrier substrate; a carrier substrate; a second semiconductor chip mounted face down on the reverse face of the carrier substrate; a third semiconductor chip on which re-arrangement wiring line layers are formed on surfaces where electrode pads are formed; and protruding electrodes for connecting the third semiconductor chip to the carrier substrate so that the third semiconductor chip is held above the first semiconductor chip.

According to the above structure, even when the kinds of the sizes of the semiconductor chips vary, it is possible to flip-chip mount the third semiconductor chip on the first semiconductor chip without interposing the carrier substrate between the first semiconductor chip and the third semiconductor chip and to provide the first and second semiconductor chips made of the same material on both faces of the first carrier substrate. As a result, it is possible to reduce the difference in the linear expansion coefficients on both faces of the first carrier substrate.

For this reason, it is possible to stack the third semiconductor chip on the first carrier substrate while suppressing warpage of the first carrier substrate and thereby save space when the semiconductor chips are mounted while ensuring good connection reliability between the third semiconductor chip and the first carrier substrate.

Further, according to one aspect of the present invention, there is provided an electronic device, comprising: a first carrier substrate; a first electronic part mounted on the first carrier substrate; a second electronic part mounted on the reverse face of the first carrier substrate; a second carrier substrate; a third electronic part mounted on the second carrier substrate; protruding electrodes for connecting the second carrier substrate to the first carrier substrate so that the second carrier substrate is held above the first electronic part; and a sealant for sealing the third electronic part.

According to the above structure, it is possible to stack the differently packaged third electronic parts on the first electronic part while suppressing warpage of the first carrier substrate and thereby realize a structure in which different kinds of parts are three-dimensionally mounted while ensuring good connection reliability between different kinds of packages.

Further, according to one aspect of the present invention, there is provided an electronic apparatus, comprising: a first carrier substrate; a first semiconductor chip mounted on the first carrier substrate; a second semiconductor chip mounted on the reverse face of the first carrier substrate; a second carrier substrate; a third semiconductor chip mounted on the second carrier substrate; protruding electrodes for connecting the second carrier substrate to the first carrier substrate so that the second carrier substrate is held above the first semiconductor chip; a sealant for sealing the third semiconductor chip; and a mother substrate on which the first carrier substrate is mounted.

According to the above structure, it is possible to stack the differently packaged third semiconductor chip on the first semiconductor chip while suppressing warpage of the first carrier substrate and thereby realize a structure in which different kinds of chips are three-dimensionally mounted while ensuring good connection reliability between different kinds of packages.

Further, according to one aspect of the present invention, there is provided a method of manufacturing a semiconductor device, comprising the steps of: mounting a first semiconductor chip face down on a first carrier substrate; mounting a second semiconductor chip face down on the reverse face of the first carrier substrate; mounting a third semiconductor chip on a second carrier substrate; forming protruding electrodes on the second carrier substrate; sealing a third semiconductor chip mounted on the second carrier substrate with a sealing resin; and connecting the second carrier substrate to the first carrier substrate via the protruding electrodes so that the second carrier substrate is held above the first semiconductor chip.

According to the above structure, it is possible to stack the second carrier substrate on the first carrier substrate in a state where the first and second semiconductor chips are provided on the first carrier substrate. As a result, it is possible to stack the differently packaged third semiconductor chip on the first semiconductor chip while suppressing warpage of the first carrier substrate and thereby realize a structure in which different kinds of chips are three-dimensionally mounted while ensuring good connection reliability between different packages.

Further, in a method of manufacturing a semiconductor device according to one aspect of the present invention, the step of sealing the third semiconductor chip. with the sealing resin comprises the steps of: integrally molding a plurality of the third semiconductor chips, which are mounted on the second carrier substrate, with the sealing resin; and cutting the second carrier substrate molded with the sealing resin into pieces so that each piece includes one of the third semiconductor chips.

According to the above structure, it is possible to seal the third semiconductor chips with sealing resin without dividing the sealing resin into cells for each third semiconductor chip and to reinforce one entire surface of the second carrier substrate with the sealing resin.

For this reason, even when the kinds or the sizes of the third semiconductor chips vary, it is possible to share a mold when the third semiconductor chips are molded and thereby make the sealing resin process efficient. Also, since space for dividing the sealing resin into cells is unnecessary, it is possible to increase the mounting area of the third semiconductor chips mounted on the second carrier substrate.

Further, according to a method of manufacturing an electronic device according to one aspect of the present invention, there is provided a method of manufacturing an electronic device, comprising the steps of: mounting a first electronic part face down on a first carrier substrate; mounting a second electronic part face down on the reverse face of the first carrier substrate; mounting a third electronic part on a second carrier substrate; forming protruding electrodes on the second carrier substrate; sealing the third electronic part, which is mounted on the second carrier substrate, with a sealing resin; and connecting the second carrier substrate to the first carrier substrate via the protruding electrodes so that the second carrier substrate is held above the first electronic part.

According to the above structure, it is possible to stack the second carrier substrate on the first carrier substrate in a state where the first and second electronic parts are provided on the first carrier substrate. As a result, it is possible to stack the differently packaged third electronic part on the first electronic part while suppressing warpage of the first carrier substrate and thereby realize a structure in which different kinds of parts are three-dimensionally mounted while ensuring good connection reliability between different kinds of packages.

### BRIEF DESCRIPTION OF THE DRAWINGS

FIG. 1 is a sectional view illustrating the structure of a semiconductor device according to a first embodiment.

FIG. 2 is a sectional view illustrating the structure of a semiconductor device according to a second embodiment.

FIGS. 3A-D are sectional views illustrating a semiconductor device according to a third embodiment.

FIG. 4A-E are sectional views illustrating a method of manufacturing a semiconductor device according to a fourth embodiment.

FIG. 5A-C are sectional views illustrating a method of manufacturing a semiconductor device according to a fourth embodiment.

FIG. 6 is a sectional view illustrating a method of manufacturing a semiconductor device according to a fifth embodiment.

FIG. 7 is a sectional view illustrating the structure of a semiconductor device according to a sixth embodiment.

FIG. 8 is a sectional view illustrating the structure of a semiconductor device according to a seventh embodiment.

### DETAILED DESCRIPTION

A semiconductor device and an electronic device and a method of manufacturing the same according to the embodiments of the present invention will now be described with reference to the drawings.

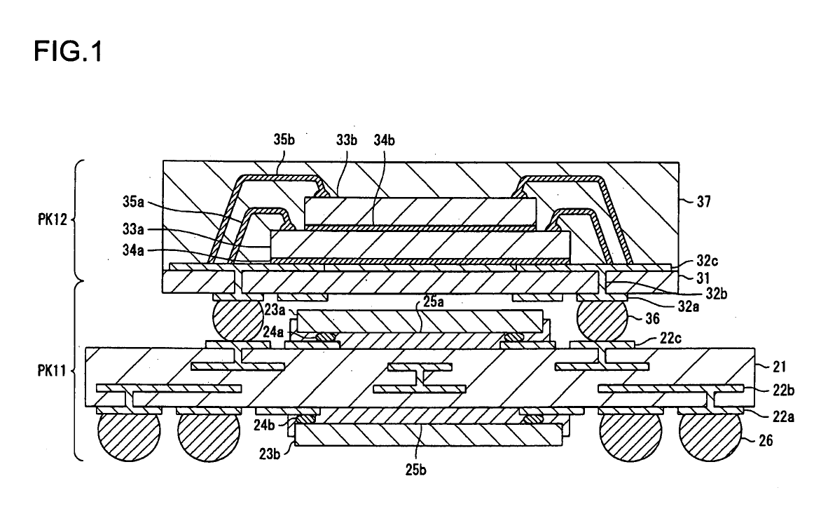

FIG. 1 is a sectional view illustrating the structure of a semiconductor device according to a first embodiment of the present invention. According to the first embodiment, a semiconductor package PK12 in which stacked semiconductor chips (or semiconductor dies) 33a and 33b are wire-bonded to a carrier substrate 31 is stacked on a semiconductor package PK11 in which semiconductor chip (or a semiconductor die) 23a and 23b are mounted on both faces of a carrier substrate 21 by anisotropic conductive film (ACF) bonding.

In FIG. 1, a carrier substrate 21 is provided in the semiconductor package PK11. Lands 22a and 22c are respectively formed on both faces of the carrier substrate 21. Internal wiring lines 22b are formed in the carrier substrate 21. The semiconductor chips 23a and 23b are flip-chip mounted on both faces of the carrier substrate 21. Protruding electrodes 24a and 24b for flip-chip mounting the semiconductor chips 23a and 23b are provided on the semiconductor chips 23a and 23b. The protruding electrodes 24a and 24b provided on the semiconductor chips 23a and 23b are bonded to the lands 22c and 22a via anisotropic conductive sheets 25a and 25b by ACF bonding. Further, protruding electrodes 26 for mounting the carrier substrate 21 on a mother substrate are provided on the lands 22a on the reverse face of the carrier substrate 21.

It is possible to reduce a difference in linear expansion coefficients on both faces of the carrier substrate 21 by mounting the semiconductor chips 23a and 23b on both faces of the carrier substrate 21 and thereby reduce warpage of the carrier substrate 21. Further, space for wire bonding or mold sealing the semiconductor chips 23a and 23b is unnecessary by mounting the semiconductor chips 23a and 23b on the carrier substrate 21 by ACF bonding. Therefore, it is possible to save space when the semiconductor chips 23a and 23b are three-dimensionally mounted and to lower the temperature when the semiconductor chips 23 are bonded to the carrier substrate 21. As a result, it is possible to reduce the warpage of the carrier substrate 21 when the carrier substrate 21 is actually used.

Moreover, the thicknesses and the sizes of the semiconductor chips 23a and 23b mounted on both faces of the carrier substrate 21 are preferably the same. However, the thicknesses or the sizes of the semiconductor chips 23a and 23b may vary.

On the other hand, a carrier substrate 31 is provided in the semiconductor package PK12. Lands 32a and 32c are respectively formed on both faces of the carrier substrate 31. Internal wiring lines 32b are formed in the carrier substrate 31. A semiconductor chip 33a is mounted face up on the carrier substrate 31 via an adhesion layer 34a. The semiconductor chip 33 is wire-bonded to the lands 32c via conductive wires 35a. Furthermore, a semiconductor chip 33b is mounted face up on the semiconductor chip 33a so as to avoid the conductive wires 35a. The semiconductor chip 33b is fixed to the semiconductor chip 33a via an adhesion layer 34b and is wire-bonded to the lands 32c via conductive wires 35b.

Further, protruding electrodes 36 for mounting the carrier substrate 31 on the carrier substrate 21 are provided on the lands 32a on the reverse face of the carrier substrate 31 so that the carrier substrate 31 is held above the semiconductor chip 23a. The protruding electrodes 36 can be arranged so as to avoid the region on which the semiconductor chip 23a is mounted. It is possible to arrange the protruding electrodes 36, for example, around a peripheral region of the reverse face of the carrier substrate 31. It is also possible to mount the carrier substrate 31 on the carrier substrate 21 by bonding the protruding electrodes 36 to the lands 22c provided on the carrier substrate 21.

Therefore, it is possible to stack the differently packaged semiconductor chips 33a and 33b on the semiconductor chips 23a and 23b while suppressing warpage of the carrier substrate 21. As a result, it is possible to stack the different kinds of packages PK11 and PK12 while ensuring good connection reliability between the carrier substrates 21 and 31 and thereby to realize a structure in which the different kinds of semiconductor chips 23a, 23b, 33a, and 33b are three-dimensionally mounted.

Further, the semiconductor chips 33a and 33b are sealed with a sealing resin 37. The sealing resin 37 can be molded using a thermosetting resin such as epoxy resin.

The sealing resin 37 is molded on one entire surface of the carrier substrate 31 on which the semiconductor chips 33a and 33b are mounted. Therefore, even when various kinds of semiconductor chips 33a and 33b are mounted on the carrier substrate 31, it is possible to share a mold when the sealing resin 37 is molded and thereby make the sealing resin process efficient. Also, since space for dividing the sealing resin 37 into cells is unnecessary, it is possible to increase the mounting area of the semiconductor chips 33a and 33b mounted on the carrier substrate 31.

For example, a dual-sided substrate, a multi-layer wiring line substrate, a built-up substrate, a tape substrate or a film substrate may be used as the carrier substrates 21 and 31. The carrier substrates 21 and 31 may be made of, for example, polyimide resin, glass epoxy resin, BT resin, a composite of aramide and epoxy, and ceramic. For example, an Au bump, a Cu bump and an Ni bump coated with solder, and solder balls may be used as the protruding electrodes 24a, 24b, 26, and 36. Since solder balls are used as the protruding electrodes 26 and 36, it is possible to stack the different kinds of packages PK11 and PK12 on each other by using regular BGA and thereby apply the manufacturing line to other fields. For example, Au wire and Al wire can be used as the conductive wires 35a and 35b. A method of providing the protruding electrodes 36 on the lands 32a of the carrier substrate 31 in order to mount the carrier substrate 31 on the carrier substrate 21 is described in the above-mentioned embodiment. However, the protruding electrodes 36 may be provided on the lands 22c of the carrier substrate 21.

Further, a method of mounting the semiconductor chip 23 on the carrier substrate 21 by ACF bonding is described in the above-mentioned embodiment. However, for example, other adhesive bonding such as nonconductive film (NCF) bonding, anisotropic conductive paste (ACP) bonding, or nonconductive paste (NCP) bonding may be used. Metal joining such as soldering or alloy joining may be used. Furthermore, the method of mounting semiconductor chip 23a and 23b on both faces of the carrier substrate 21, respectively, is described in the above-mentioned embodiment. However, a plurality of semiconductor chips may also be mounted on the carrier substrate 21.

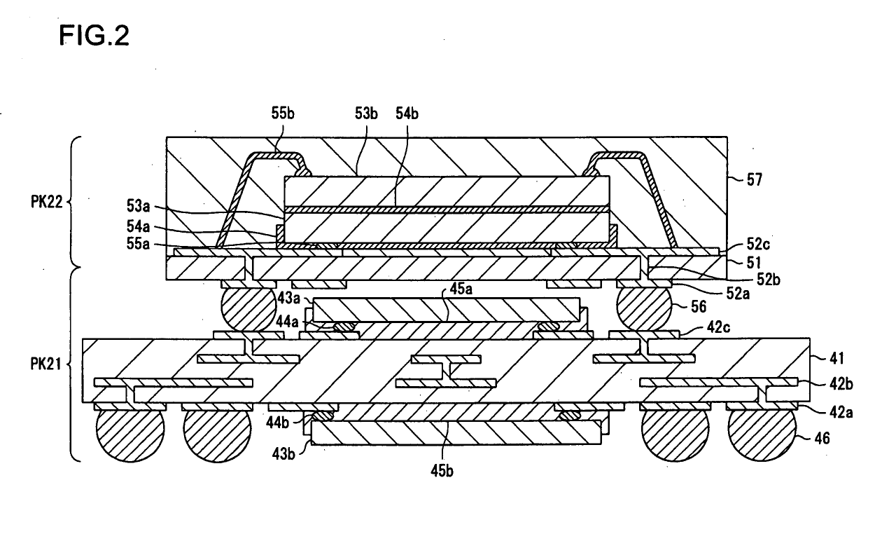

FIG. 2 is a sectional view illustrating the structure of a semiconductor device according to a second embodiment of the present invention. According to the second embodiment, a semiconductor package PK22 in which stacked semiconductor chips 53a and 53b are flip-chip mounted on and wire-bonded to a carrier substrate 51, respectively, is stacked on a semiconductor package PK21 in which semiconductor chips 43a and 43b are mounted on both faces of a carrier substrate 41 by ACF bonding.

In FIG. 2, a carrier substrate 41 is provided in the semiconductor package PK21. Lands 42a and 42c are respectively formed on both faces of the carrier substrate 41. Internal wiring lines 42b are formed in the carrier substrate 41. Semiconductor chips 43a and 43b are flip-chip mounted on both faces of the carrier substrate 41, respectively. Protruding electrodes 44a and 44b for flip-chip mounting the semiconductor chips 43a and 43b are provided on the semiconductor chips 43a and 43b. The protruding electrodes 44a and 44b provided on the semiconductor chips 43a and 43b are bonded to the lands 42c and 42a via anisotropic conductive sheets 45a and 45b by ACF bonding. Protruding electrodes 46 for mounting the carrier substrate 41 on a mother substrate are provided on the lands 42a on the reverse face of the carrier substrate 41.

It is possible to reduce the difference in the linear expansion coefficients on both faces of the carrier substrate 41 by mounting the semiconductor chips 43a and 43b on both faces of the carrier substrate 41 and thereby reduce warpage of the carrier substrate 41. Space for wire bonding or mold sealing the semiconductor chips 43a and 43b is unnecessary by mounting the semiconductor chips 43a and 43b on the carrier substrate 41 by ACF bonding. Therefore, it is possible to save space when the semiconductor chips 43a and 43b are three-dimensionally mounted and to lower the temperature when the semiconductor chips 43a and 43b are bonded to the carrier substrate 41. As a result, it is possible to reduce warpage of the carrier substrate 41 when the carrier substrate 41 is actually used.

On the other hand, a carrier substrate 51 is provided in the semiconductor package PK22. Lands 52a and 52c are respectively formed on both faces of the carrier substrate 51. Internal wiring lines 52b are formed in the carrier substrate 51. A semiconductor chip 53a is flip-chip mounted on the carrier substrate 51. Protruding electrodes 55a for flip-chip mounting the semiconductor chip 53a are provided on the semiconductor chip 53a. The protruding electrodes 55a provided on the semiconductor chip 53a are bonded to the lands 52c via an anisotropic conductive sheet 54a by ACF bonding. Furthermore, a semiconductor chip 53b is mounted face up on the semiconductor chip 53a. The semiconductor chip 53b is fixed to the semiconductor chip 53a via an adhesion layer 54b and is wire-bonded to the lands 52c via conductive wires 55b.

It is possible to stack the semiconductor chip 53b of a size equal to or large than the semiconductor chip 53a on the semiconductor chip 53a by mounting the semiconductor chip 53b face up on the face-down mounted semiconductor chip 53a without interposing a carrier substrate and thereby reduce the mounting area.

Further, protruding electrodes 56 for mounting the carrier substrate 51 on the carrier substrate 41 are provided on the lands 52a on the reverse face of the carrier substrate 51 so that the carrier substrate 51 is held above the semiconductor chip 43a. The protruding electrodes 56 are arranged so as to avoid the region on which the semiconductor chip 43a is mounted. It is possible to arrange the protruding electrodes 56, for example, around a peripheral region of the reverse face of the carrier substrate 51. It is also possible to mount. the carrier substrate 51 on the carrier substrate 41 by bonding the protruding electrodes 56 to the lands 42c provided on the carrier substrate 41.

Therefore, it is possible to stack the differently packaged semiconductor chips 53a and 53b on the semiconductor chips 43 while suppressing warpage of the carrier substrate 41. As a result, it is possible to stack the different kinds of packages PK21 and PK22 while ensuring good connection reliability between the carrier substrates 41 and 51 and thereby realize a structure in which the different kinds of semiconductor chips 43a, 43b, 53a, and 53b are three dimensionally mounted.

For example, solder balls may be used as the protruding electrodes 46 and 56. Therefore, it is possible to stack the different kinds of packages PK21 and PK22 on each other by using regular BGA and thereby apply the manufacturing line to other fields.

Further, the semiconductor chips 53a and 53b are sealed with a sealing resin 57. The sealing resin 57 may be molded using a thermosetting resin such as epoxy resin.

The sealing resin 57 is provided on one entire surface of the carrier substrate 51 on which the semiconductor chips 53a and 53b are mounted. Therefore, even when the various kinds of semiconductor chips 53a and 53b are mounted on the carrier substrate 51, it is possible to share a mold when the sealing resin 57 is molded and thereby make the sealing resin process efficient. Also, since space for dividing the sealing resin 57 into cells is unnecessary, it is possible to increase the mounting area of the semiconductor chips 53a and 53b mounted on the carrier substrate 51.

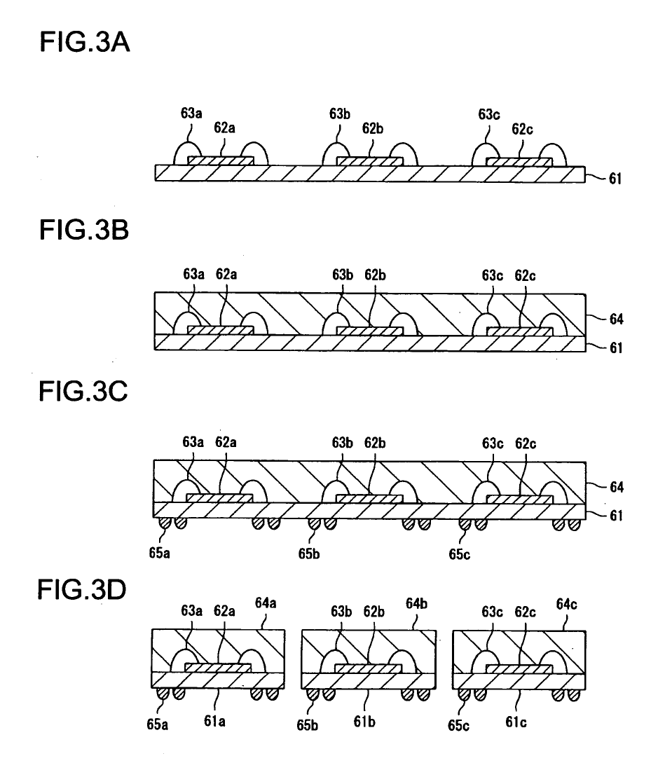

FIG. 3 is a sectional view illustrating a method of manufacturing a semiconductor device according to a third embodiment of the present invention. According to the third embodiment, after a plurality of semiconductor chips 62a to 62c are integrally molded with a sealing resin 64, a carrier substrate 61 and the sealing resin 64 are cut into pieces so that each piece includes one of the semiconductor chips 62a to 62c. Therefore, sealing resin 64a to 64c is respectively formed on one entire surface of carrier substrates 61a to 61c on which the semiconductor chips 62a to 62c are respectively mounted.

In FIG. 3(a), a mounting region on which the plurality of semiconductor chips 62a to 62c is mounted is provided in the carrier substrate 61. The plurality of semiconductor chips 62a to 62c is mounted on the carrier substrate 61 and is wire-bonded to the carrier substrate 61 via conductive wires 63a to 63c. Other than the method of wire-bonding the semiconductor chips 62a to 62c to the carrier substrate 61, the semiconductor chips 62a to 62c may be flip-chip mounted on the carrier substrate 61, and a structure in which the semiconductor chips 62a to 62c are stacked may be mounted on the carrier substrate 61.

Next, as illustrated in FIG. 3(b), the plurality of semiconductor chips 62a to 62c mounted on the carrier substrate 61 are integrally molded with a sealing resin 64. Even when the various kinds of semiconductor chips 62a to 62c are mounted on the carrier substrate 61 by integrally molding the plurality of semiconductor chips 62a to 62c with the sealing resin 64, it is possible to share a mold when the semiconductor chips 62a to 62c are molded and thereby make the sealing resin process efficient. Also, since space for dividing the sealing resin 64 into cells is unnecessary, it is possible to increase the mounting area of the semiconductor chips 62a to 62c mounted on the carrier substrate 61.

Next, as illustrated in FIG. 3(c), protruding electrodes 65a to 65c made of solder balls are respectively formed on the reverse faces of the carrier substrates 61a to 61c. As illustrated in FIG. 3(d), by cutting the carrier substrate 61 and the sealing resin 64 so that each cut piece includes one of the semiconductor chips 62a to 62c, the carrier substrate 61 is divided into the carrier substrates 61a to 61c on which the semiconductor chips 62a to 62c are respectively sealed with the sealing resins 64a to 64c.

It is possible to respectively form the sealing resins 64a to 64c on one entire surface of the carrier substrates 61a to 61c on which the semiconductor chips 62a to 62c are mounted by integrally cutting the carrier substrate 61 and the sealing resin 64. Therefore, it is possible to improve the rigidity of the region in which the protruding electrodes 65a to 65c are arranged while preventing the manufacturing process from becoming complicated and thereby reduce warpage of the carrier substrates 61a to 61c. Moreover, after cutting the carrier substrate 61 and the sealing resin 64 into pieces, the protruding electrodes 65a to 65c may be formed in each piece.

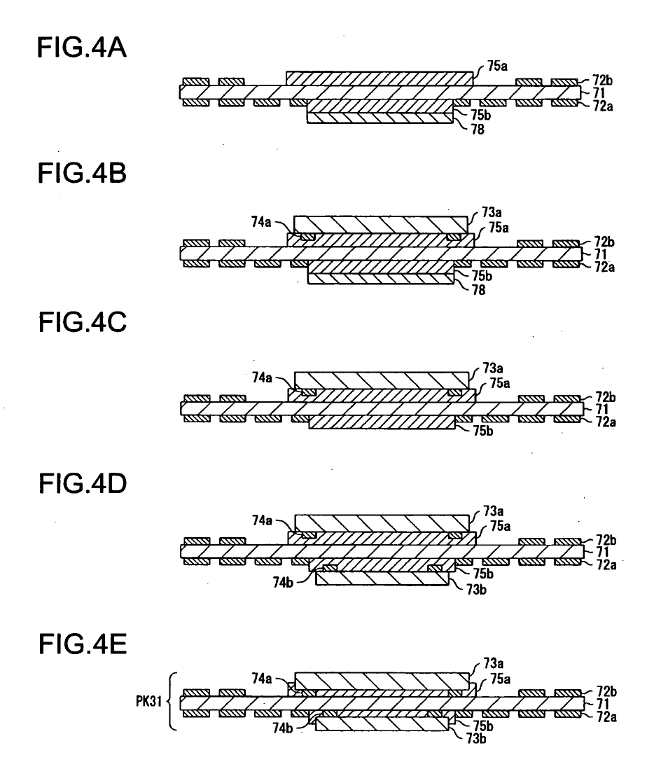

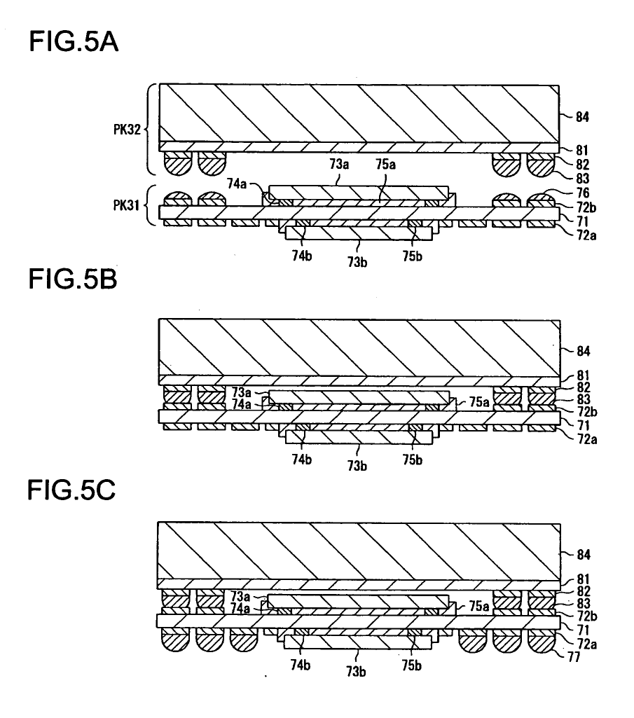

FIGS. 4 and 5 are sectional views illustrating a method of manufacturing a semiconductor device according to a fourth embodiment of the present invention. According to the fourth embodiment, a semiconductor package PK32 sealed with a sealing resin 84 is stacked on a semiconductor package PK31 in which semiconductor chips 73a and 73b are mounted on a carrier substrate 71 by ACF bonding.

In FIG. 4(a), a carrier substrate 71 is provided. Lands 72a and 72b are respectively formed on both faces of the carrier substrate 71. Anisotropic conductive sheets 75a and 75b are attached to both faces of the carrier substrate 71. A separator 78 is attached to the anisotropic conductive sheet 75b. Moreover, the separator 78 may be made of PET.

As illustrated in FIG. 4(b), the semiconductor chip 73a is provisionally pressed on the anisotropic conductive sheet 75a while positioning the semiconductor chip 73a. When the semiconductor chip 73a is provisionally pressed, as illustrated in FIG. 4(c), the separator 78 on the anisotropic conductive sheet 75b is peeled off. As illustrated in FIG. 4(d), the semiconductor chip 73b is provisionally pressed on the anisotropic conductive sheet 75b while positioning the semiconductor chip 73b.

When the semiconductor chips 73a and 73b are provisionally pressed on the anisotropic conductive sheets 75a and 75b, respectively, a load is applied to the semiconductor chips 73a and 73b from above and below while heating the carrier substrate 71 on which the semiconductor chips 73a and 73b are provisionally pressed. As illustrated in FIG. 4(e), the semiconductor chips 73a and 73b are bonded to the carrier substrate 71 via the protruding electrodes 74a and 74b by ACF bonding to thereby manufacture a semiconductor package PK31 in which the semiconductor chips 73a and 73b are mounted on both faces of the carrier substrate 71.

Next, in FIG. 5(a), a carrier substrate 81 is provided in a semiconductor package PK32. Lands 82 are respectively formed on the reverse face of the carrier substrate 81. Protruding electrodes 83 made of solder balls are provided on the lands 82. Further, a semiconductor chip is mounted on the carrier substrate 81. One entire surface of the carrier substrate 81 on which the semiconductor chip is mounted is sealed with a sealing resin 84. A wire-bonded semiconductor chip may be mounted on the carrier substrate 81. A semiconductor chip may be flip-chip mounted on the carrier substrate 81. A structure in which semiconductor chips are stacked may be mounted on the carrier substrate 81.

When the semiconductor package PK32 is stacked on the semiconductor package PK31, flux 76 is provided on the lands 72b of the carrier substrate 71. Soldering paste instead of flux 76 may be provided on the lands 72b of the carrier substrate 71.

Next, as illustrated in FIG. 5(b), protruding electrodes 83 are bonded to the lands 72b by mounting the semiconductor package PK32 on the semiconductor package PK31 and performing a reflow process.

Next, as illustrated in FIG. 5(c), protruding electrodes 77 for mounting the carrier substrate 71 on the lands 72a on the reverse face of the carrier substrate 71 on a mother substrate are formed.

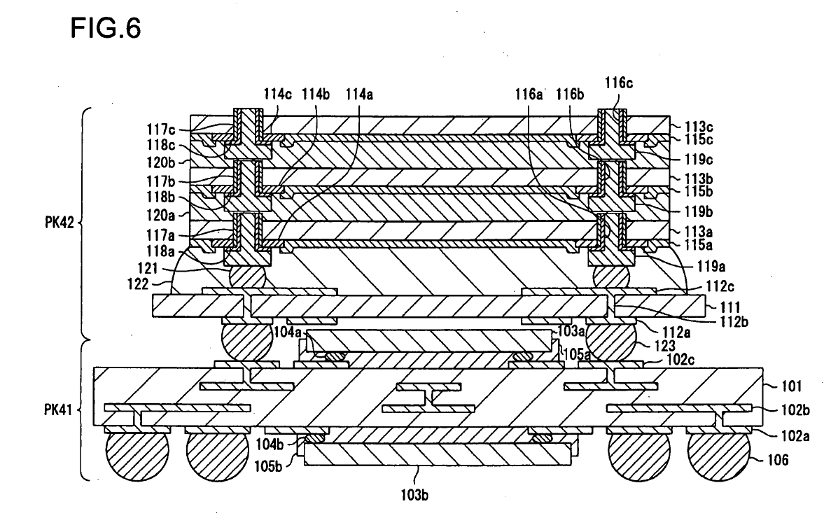

FIG. 6 is a sectional view illustrating the structure of a semiconductor device according to a fifth embodiment of the present invention. According to the fifth embodiment, a structure in which, semiconductor chips 113a to 113c are stacked is three-dimensionally mounted on a carrier substrate 101 on both faces of which semiconductor chips 103a and 103b are flip-chip mounted.

In FIG. 6, the carrier substrate 101 is provided in a semiconductor package PK41. Lands 102a and 102c are respectively formed on both faces of the carrier substrate 101. Internal wiring lines 102b are formed in the carrier substrate 101. The semiconductor chips 103a and 103b are flip-chip mounted on both faces of the carrier substrate 101. Protruding electrodes 104a and 104b for flip-chip mounting the semiconductor chips 103a and 103b are respectively provided on the semiconductor chips 103a and 103b.

The protruding electrodes 104a and 104b provided on the semiconductor chips 103a and 103b are respectively bonded to the lands 102c and 102a via anisotropic conductive sheets 105a and 105b by ACF bonding. When the semiconductor chips 103a and 103b are mounted on the carrier substrate 101, other than the bonding method using the ACF bonding, adhesive bonding such as NCF bonding and metal joining such as soldering and alloy joining may be used. Further, protruding electrodes 106 for mounting the carrier substrate 101 on a mother substrate are provided on the lands 102a provided on the reverse face of the carrier substrate 101. It is possible to reduce the difference in the linear expansion coefficients on both faces of the carrier substrate 101 by respectively mounting the semiconductor chips 103a and 103b on both faces of the carrier substrate 101 and thereby reduce warpage of the carrier substrate 101.

On the other hand, a carrier substrate 111 is provided in a semiconductor package PK42. Lands 112a and 112c are respectively formed on both faces of the carrier substrate 111. Internal wiring. lines 112b are formed in the carrier substrate 111.

Further, electrode pads 114a to 114c are provided in the semiconductor chips 113a to 113c. Insulating films 115a to 115c are respectively provided in the semiconductor chips 11 3a to 11 3c so that the electrode pads 114a to 114c are exposed. Through holes 116a to 116c are respectively formed in the semiconductor chips 113a to 113c so as to correspond to the positions of the electrode pads 114a to 114c. Through electrodes 119a to 119c are respectively formed in the through holes 116a to 116c via insulating films 117a to 117c and conductive films 118a to 118c.

The semiconductor chips 113a to 113c in which the through electrodes 119a to 119c are formed are stacked via the through electrodes 119a to 119c. Resins 120a and 120b are implanted into gaps among the semiconductor chips 113a to 113c.

Further, protruding electrodes 121 for flip-chip mounting the structure in which the semiconductor chips 113a to 113c are stacked are provided on the through electrodes 119a formed in the semiconductor chip 113a. The protruding electrodes 121 are bonded to the lands 112c provided on the carrier substrate 111. The surface of the semiconductor chip 113a mounted on the carrier substrate 111 is sealed with a sealing resin 122. The structure in which the semiconductor chips 113a to 113c are stacked is mounted on the carrier substrate 111.

Further, protruding electrodes 123 for mounting the carrier substrate 111 on the carrier substrate 101 are provided on the lands 112a provided on the reverse face of the carrier substrate 111 so that the carrier substrate 111 is provided above the semiconductor chip 103a.

The protruding electrodes 123 can be arranged so as to avoid the region on which the semiconductor chip 103a is mounted. For example, the protruding electrodes 123 may be arranged around a peripheral region of the carrier substrate 111. It is possible to mount the carrier substrate 111 on the carrier substrate 101 by bonding the protruding electrodes 123 to the lands 102c provided on the carrier substrate 101.

Therefore, it is possible to mount a structure in which the semiconductor chips 111a to 111c are stacked on the semiconductor chip 103a while suppressing warpage of the carrier substrate 101.

As a result, it is possible to stack the different kinds of packages PK41 and PK42 while ensuring good connection reliability between the carrier substrates 101 and 111 and thereby realize a structure in which the different kinds of semiconductor chips 103a, 103b, and 113a to 113c are three-dimensionally mounted while suppressing an increase in the height when the packages PK41 and PK42 are stacked.

For example, an Au bump, a Cu bump and an Ni bump coated with solder, or solder balls may be used as the protruding electrodes 104a, 104b, 106, 121, and 123. The method of mounting the three-layer structure of the semiconductor chips 113a to 113c on the carrier substrate 111 is described in the above-mentioned embodiment. However, the structure in which the semiconductor chips are stacked, which is mounted on the carrier substrate 111, may consist of two, four or more layers.

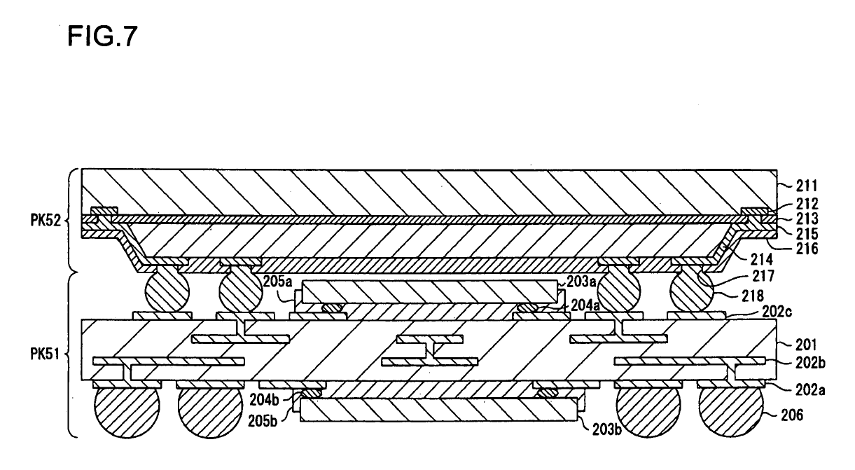

FIG. 7 is a sectional view illustrating a structure of a semiconductor device according to a sixth embodiment of the present invention. According to the sixth embodiment, a W-CSP (a wafer level chip size package) is three-dimensionally mounted on a carrier substrate 201 on both faces of which the semiconductor chips 203a and 203b are flip-chip mounted.

In FIG. 7, the carrier substrate 201 is provided in a semiconductor package PK51. Lands 202a and 202c are respectively formed on both faces of the carrier substrate 201. Internal wiring lines 202b are formed in the carrier substrate 201. The semiconductor chips 203a and 203b are flip-chip mounted on both faces of the carrier substrate 201. Protruding electrodes 204a and 204b for flip-chip mounting the semiconductor chips 203a and 203b are provided on the semiconductor chips 203a and 203b.

The protruding electrodes 204a and 204b provided on the semiconductor chips 203a and 203b are bonded to the lands 202c and 202a via anisotropic conductive sheets 205a and 205b by ACF bonding. Further, protruding electrodes 206 for mounting the carrier substrate 201 on a mother substrate are provided on the lands 202a provided on the reverse face of the carrier substrate 201. It is possible to reduce the difference in the linear expansion coefficients on both faces of the carrier substrate 201 by respectively mounting the semiconductor chips 203a and 203b on both faces of the carrier substrate 201 and thereby reduce warpage of the carrier substrate 201.

On the other hand, a semiconductor chip 211 is provided in a semiconductor package PK52. Electrode pads 212 are provided on the semiconductor chip 211. An insulating film 213 is provided so as to expose the electrode pads 212. A stress-relieving layer 214 is formed on the semiconductor chip 211 so that the electrode pads 212 are exposed. A re-arrangement wiring line 215 extending on the stress-relieving layer 214 is formed on the electrode pads 212. A solder resist film 216 is formed on the re-arrangement wiring line 215. Apertures 217 for exposing the re-arrangement wiring line 215 on the stress-relieving layer 214 are formed in the solder resist film 216. Protruding electrodes 218 for mounting the semiconductor chip 211 face down on the carrier substrate 201 are provided on the re-arrangement wiring line 215 exposed through the apertures 217 so that the semiconductor package PK52 is provided above the semiconductor chip 203a.

The protruding electrodes 218 can be are arranged so as to avoid the region on which the semiconductor chip 203a is mounted, for example, around a peripheral region of the semiconductor chip 211. It is possible to mount the semiconductor package PK52 on the carrier substrate 201 by bonding the protruding electrodes 218 to the lands 202c provided on the carrier substrate 201.

Therefore, it is possible to stack the W-CSP on the carrier substrate 201 on both faces of which the semiconductor chips 203a and 203b are flip-chip mounted, while suppressing warpage of the carrier substrate 201. Therefore, even when the kinds or the sizes of the semiconductor chips 203a, 203b, and 211 vary, it is possible to three-dimensionally mount the semiconductor chips 211 on the semiconductor chips 203 without interposing a carrier substrate between the semiconductor chips 203 and 211 and to improve the connection reliability between the carrier substrate 201 and the semiconductor chips 211. As a result, it is possible to save space when the semiconductor chips 203a, 203b, and 211 are mounted while suppressing the deterioration of the reliability of the three-dimensionally mounted semiconductor chips 203a, 203b, and 211.

When the semiconductor package PK52 is mounted on the carrier substrate 201, adhesive bonding such as ACF bonding or NCF bonding may be used. Metal joining such as soldering or alloy joining may be used. For example, an Au bump, a Cu bump and an Ni bump coated with solder, and solder balls may be used as the protruding electrodes 204a, 204b, 206, and 218. The method of mounting the semiconductor package PK52 on one semiconductor chip 203a flip-chip mounted on the carrier substrate 201 is described in the above-mentioned embodiment. However, the semiconductor package PK52 may also be mounted on a plurality of semiconductor chips flip-chip mounted on the carrier substrate 201.

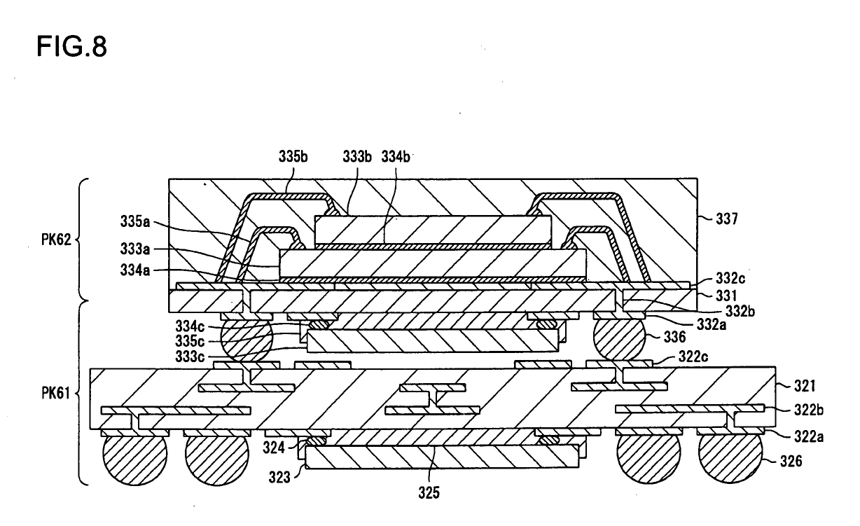

FIG. 8 is a sectional view illustrating the structure of a semiconductor device according to a seventh embodiment of the present invention. According to the seventh embodiment, a semiconductor package PK62 on the surface of which stacked semiconductor chips 333a and 333b are mounted and on the reverse face of which a semiconductor chip 333c is mounted is stacked on a semiconductor package PK61 in which a semiconductor chip 323 is mounted by ACF bonding.

In FIG. 8, the carrier substrate 321 is provided in a semiconductor package PK61. Lands 322a and 322c are respectively formed on both faces of the carrier substrate 321. Internal wiring lines 322b are formed in the carrier substrate 321. The semiconductor chip 323 is flip-chip mounted on the reverse face of the carrier substrate 321 so that the reverse face thereof is exposed. Protruding electrodes 324 for flip-chip mounting the semiconductor chip 323 are provided on the semiconductor chip 323. The protruding electrodes 324 provided on the semiconductor chip 323 are bonded to the lands 322a via an anisotropic conductive sheet 325 by ACF bonding. Protruding electrodes 326 for mounting the carrier substrate 321 on a mother substrate are provided on the lands 322a on the reverse face of the carrier substrate 321.

Since the semiconductor chip 323 is mounted on the carrier substrate 321 by ACF bonding, a space for performing wire bonding or mold sealing is unnecessary. Therefore, it is possible to save space when the semiconductor chip 323 is three-dimensionally mounted and to lower the temperature when the semiconductor chip 323 is bonded to the carrier substrate 321. As a result, it is possible to reduce warpage of the carrier substrate 321 when the carrier substrate 321 is actually used.

On the other hand, a carrier substrate 331 is provided in a semiconductor package PK62. Lands 332a and 332c are respectively formed on both faces of the carrier substrate 331. Internal wiring lines 332b are formed in the carrier substrate 331. A semiconductor chip 333a is mounted face up on the carrier substrate 331 via an adhesion layer 334a. The semiconductor chip 333a is wire-bonded to the lands 332c via conductive wires 335a. Furthermore, a semiconductor chip 333b is mounted face up on the semiconductor chip 333a so as to avoid the conductive wires 335a. The semiconductor chip 333b is fixed to the semiconductor chip 333a via an adhesion layer 334b and is wire-bonded to the lands 332c via conductive wires 335b.

Further, a semiconductor chip 333c is flip-chip mounted on the reverse face of the carrier substrate 331. Protruding electrodes 334c for flip-chip mounting the semiconductor chip 333c are provided on the semiconductor chip 333c. The protruding electrodes 334c provided on the semiconductor chip 333c are bonded to the lands 332a via an anisotropic conductive sheet 335c by ACF bonding. Moreover protruding electrodes 336 for mounting the carrier substrate 331 on the carrier substrate 321 are provided on the lands 332a on the reverse face of the carrier substrate 331. It is possible to mount the carrier substrate 31 on the carrier substrate 321 by bonding the protruding electrodes 336 to the lands 322c provided on the carrier substrate 321.

It is possible to reduce the difference in the linear expansion coefficients on the surface of the carrier substrate 331 by mounting the semiconductor chips 333a and 333b on the carrier substrate 331 and mounting the semiconductor chip 333c on the reverse face of the carrier substrate 331 and thereby reduce warpage of the carrier substrate 331.

Therefore, it is possible to stack the differently packaged semiconductor chips 333a to 333c on the semiconductor chips 323 while suppressing warpage of the carrier substrate 331. As a result, it is possible to stack the different kinds of packages PK61 and PK62 while ensuring good connection reliability between the carrier substrates 321 and 331 and thereby realize a structure in which the different kinds of semiconductor chips 323 and 333a to 333c are three-dimensionally mounted.

Further, the semiconductor chips 333a and 333b are sealed with a sealing resin 337. The sealing resin 337 can be molded using a thermosetting resin such as epoxy resin.

Moreover, the method of mounting the semiconductor chips on both faces of the carrier substrate is described in the above-mentioned embodiment. However, the semiconductor chips may be mounted on one face of the carrier substrate and dummy chips may be mounted on the reverse face of the carrier substrate. Therefore, the dummy chips may be made of a metal-based material, a ceramic-based material, and a resin-based material other than a semiconductor-based material. It is possible to remove limitations on materials capable of being mounted on the carrier substrate and thereby precisely control the warpage of the carrier substrate.

Further, the above-mentioned semiconductor devices and electronic devices can be applied to electronic apparatuses such as liquid crystal displays, mobile telephones, portable information terminals, video cameras, digital cameras, and mini disc (MD) players to thereby miniaturize and lighten the electronic apparatuses and to improve the reliability of the electronic apparatuses.

Further, a method of mounting the semiconductor chips or the semiconductor packages is described in the above-mentioned embodiment. However, the present invention is not necessarily limited to this method of mounting semiconductor chips or semiconductor packages. For example, ceramic elements such as surface acoustic wave (SAW) elements, optical elements such as optical modulators and optical switches, and various sensors such as magnetic sensors and biosensors may also be mounted.

What is claimed is:

1. A semiconductor device, comprising:
a first carrier substrate;
a first semiconductor chip mounted face down on the first carrier substrate;
a second semiconductor chip mounted face down on a reverse face of the first carrier substrate;
a second carrier substrate;
a third semiconductor chip mounted on the second carrier substrate; and
protruding electrodes connecting the second carrier substrate to the first carrier substrate so that the second carrier substrate is held above the first semiconductor chip.

2. The semiconductor device according to claim 1, wherein the second carrier substrate is fixed to the first carrier substrate so as to be mounted on the first semiconductor chip.

3. The semiconductor device according to claim 1, further comprising a sealant for sealing the third semiconductor chip.

4. The semiconductor device according to claim 3, wherein the sealant further comprises a molded resin.

5. The semiconductor device according to claim 4,
wherein a position of a sidewall of the sealant coincides with a sidewall of the second carrier substrate.

6. The semiconductor device according to claim 1,
wherein the first semiconductor chip and the second semiconductor chip are connected to the first carrier substrate by pressure welding.

7. The semiconductor device according to claim 1,
wherein, at the same temperature, an elastic modulus of a semiconductor device comprising the first carrier substrate is different from an elastic modulus of a semiconductor device comprising the second carrier substrate.

8. The semiconductor device according to claim 1,
wherein the first carrier substrate on which the first semiconductor chip and the second semiconductor chip are mounted further comprises a flip-chip-mounted ball grid array, and
wherein the second carrier substrate on which the third semiconductor chip is mounted further comprises at least one of a mold-sealed ball grid array and a chip size package.

9. The semiconductor device according to claim 1,
wherein the third semiconductor chip comprises a structure in which a plurality of chips is stacked.

10. The semiconductor device according to claim 1,
wherein the third semiconductor chip comprises a structure in which a plurality of chips is arranged in parallel on the second carrier substrate.

11. An electronic device, comprising:
a first carrier substrate;
a first semiconductor chip mounted face down on at least one face of the first carrier substrate;
a second carrier substrate;
a second semiconductor chip mounted on the second carrier substrate;
a third semiconductor chip mounted on a reverse face of the second carrier substrate; and
protruding electrodes bonding the second carrier substrate to the first carrier substrate.

12. A semiconductor device, comprising:
a carrier substrate;
a first semiconductor chip mounted face down on the carrier substrate;
a second semiconductor chip mounted face down on a reverse face of the carrier substrate;
a third semiconductor chip on which re-arrangement wiring line layers are formed on surfaces where electrode pads are formed; and
protruding electrodes connecting the third semiconductor chip to the carrier substrate so that the third semiconductor chip is held above the first semiconductor chip.

13. An electronic device, comprising:
a first carrier substrate;
a first electronic part mounted on the first carrier substrate;
a second electronic part mounted on a reverse face of the first carrier substrate;
a second carrier substrate;
a third electronic part mounted on the second carrier substrate;
protruding electrodes connecting the second carrier substrate to the first carrier substrate so that the second carrier substrate is held above the first electronic part; and
a sealant for sealing the third electronic part.

14. An electronic device, comprising:
a first carrier substrate;
a semiconductor chip mounted on the first carrier substrate;
a second semiconductor chip mounted on a reverse face of the first carrier substrate;
a second carrier substrate;
a third semiconductor chip mounted on the second carrier substrate;
protruding electrodes connecting the second carrier substrate to the first carrier substrate so that the second carrier substrate is held above the first semiconductor chip;
a sealant for sealing the third semiconductor chip; and
a mother substrate on which the first carrier substrate is mounted.

15. A method of manufacturing a semiconductor device, comprising the steps of:
mounting a first semiconductor chip face down on a first carrier substrate;
mounting a second semiconductor chip face down on a reverse face of the first carrier substrate;
mounting a third semiconductor chip on a second carrier substrate;
forming protruding electrodes on the second carrier substrate;
sealing a third semiconductor chip mounted on the second carrier substrate with a sealing resin; and
connecting the second carrier substrate to the first carrier substrate via protruding electrodes so that the second carrier substrate is held above the first semiconductor chip.

16. The method of manufacturing a semiconductor device according to claim 15, wherein the step of sealing the third semiconductor chip with the sealing resin comprises the steps of:
integrally molding a plurality of the third semiconductor chips, which are mounted on the second carrier substrate, with the sealing resin; and
cutting the second carrier substrate molded with the sealing resin into pieces so that each piece includes one of the third semiconductor chips.

17. A method of manufacturing an electronic device, comprising. the steps of:
mounting a first electronic part face down on a first carrier substrate;
mounting a second electronic part face down on a reverse face of the first carrier substrate;
mounting a third electronic part on a second carrier substrate;
forming protruding electrodes on the second carrier substrate;
sealing the third electronic part, which is mounted on the second carrier substrate, with a sealing resin; and
connecting the second carrier substrate to the first carrier substrate via the protruding electrodes so that the second carrier substrate is held above the first electronic part.
